(19) United States
(12) Patent Application Publication
(10) Pub. No.: US 2014/0051246 A1
(43) Pub. Date: Feb. 20, 2014

(54) METHODS OF FABRICATING A SEMICONDUCTOR DEVICE

(71) Applicant: Samsung Electronics Co., Ltd., Suwon-si (KR)

(72) Inventors: Chae Lyoung Kim, Seoul (KR); Ilyoung Yoon, Hwaseong-si (KR); Boun Yoon, Seoul (KR)

(73) Assignee: Samsung Electronics Co., Ltd., Suwon-si (KR)

(21) Appl. No.: 13/962,479

(22) Filed: Aug. 8, 2013

(30) Foreign Application Priority Data
Aug. 20, 2012 (KR) 10-2012-0090853

(51) Int. Cl. H01L 21/306

(52) U.S. Cl. CPC H01L 21/30625
USPC 438/666

(57) ABSTRACT

Methods of fabricating a semiconductor device are provided. The methods may include preparing a semiconductor substrate, forming insulating patterns including a trench on the semiconductor substrate, conformally forming a metal layer covering an inner surface of the trench on the insulating patterns, conformally forming a protecting layer on the metal layer, and performing a chemical mechanical polishing (CMP) process on the protecting layer and the metal layer until top surfaces of the insulating patterns are exposed, thereby forming a metal pattern and a protecting pattern in the trench. The CMP process may use a slurry including polishing particles having negative charges.

### CROSS-REFERENCE TO RELATED APPLICATIONS

This U.S. non-provisional patent application claims priority under 35 U.S.C. §119 to Korean Patent Application No. 10-2012-0090853, filed on Aug. 20, 2012, the entirety of which is incorporated by reference herein.

### BACKGROUND

The inventive concept relates to methods of fabricating a semiconductor device and, more particularly, to methods of fabricating a semiconductor device using a chemical mechanical polishing method having improved reliability.

A chemical mechanical polishing (CMP) process may be used as a planarizing technique for removing a height difference of a predetermined layer formed on a substrate in fabrication of a semiconductor device. The CMP process may correspond to a wide planarizing technique using a polishing pad and a slurry. In the CMP process, the polishing pad may contact an uneven surface of the wafer, and then the polishing pad and the wafer may be relatively moved over the slurry therebetween. Thus, the uneven surface of the wafer may be chemically and mechanically etched to be planarized. The CMP process may be used for etching a trench filling oxide layer of a shallow trench isolation process, a poly-silicon layer of a self-aligned contact process, and/or a metal layer of a metal interconnection process. Recently, CMP is being applied in various fields.

### SUMMARY

Embodiments of the inventive concept may provide methods of fabricating a semiconductor device with improved reliability.

In one aspect, a method of fabricating a semiconductor device may include preparing a semiconductor substrate; forming insulating patterns including a trench on the semiconductor substrate; conformally forming a metal layer covering an inner surface of the trench on the insulating patterns; conformally forming a protecting layer on the metal layer; and performing a chemical mechanical polishing (CMP) process on the protecting layer and the metal layer until top surfaces of the insulating patterns are exposed, thereby forming a metal pattern and a protecting pattern in the trench. The CMP process may use a slurry including polishing particles having negative charges.

In an embodiment, the slurry may have a pH of about 1 to about 4; and the protecting layer may have negative charges as a result of the slurry. In this case, for example, the protecting layer may include a silicon oxide layer and/or a titanium oxide layer.

In an embodiment, the slurry may have a pH of about 1 to about 4; and the protecting layer may have positive charges as a result of the slurry. In this case, for example, the protecting layer may include a silicon nitride layer and/or an aluminum oxide layer.

In an embodiment, the method may further include removing the protecting pattern after performing the CMP process.

In an embodiment, the polishing particles may be silica particles.

In an embodiment, the metal layer may include at least one of tungsten, aluminum, copper, or any alloy thereof.

In an embodiment, a thickness of the metal layer may be less than a half of a width of the trench.

In another aspect, a method of fabricating a semiconductor device may include forming an insulating pattern having a contact hole and a photo alignment key trench on a semiconductor substrate, the photo alignment key trench having a width greater than a width of the contact hole; forming a metal plug layer on the insulating pattern, the metal plug layer filling the contact hole and covering an inner surface of the photo alignment key trench; conformally forming a protecting layer on the metal plug layer; and performing a chemical mechanical polishing (CMP) process on the protecting layer and the metal plug layer utilizing a slurry including charged polishing particles. The protecting layer may include a material having a charge of the same polarity as the polishing particles of the slurry.

In an embodiment, the slurry may have a pH of about 1 to about 4; and the protecting layer may have negative charges as a result of the slurry.

In an embodiment, the protecting layer may include a silicon oxide layer and/or a titanium oxide layer.

In an embodiment, the polishing particles may be silica particles.

In an embodiment, performing the CMP process may include forming a metal pattern and a protecting pattern covering a surface of the metal pattern in the photo alignment key trench and a metal plug in the contact hole.

In an embodiment, the method may further include removing the protecting pattern after performing the CMP process.

### BRIEF DESCRIPTION OF THE DRAWINGS

The inventive concept will become more apparent in view of the attached drawings and accompanying detailed description.

FIG. 1A is a plan view illustrating a wafer for fabricating a semiconductor device;

FIG. 1B is an enlarged plan view of a portion “A” of FIG. 1A;

FIG. 1C is a plan view illustrating shapes of photo alignment keys;

FIG. 2A to 2F are cross-sectional views illustrating a method of fabricating a semiconductor device according to some embodiments of the inventive concept; and

FIG. 3A to 3D are cross-sectional views illustrating a method of fabricating a semiconductor device according to some embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

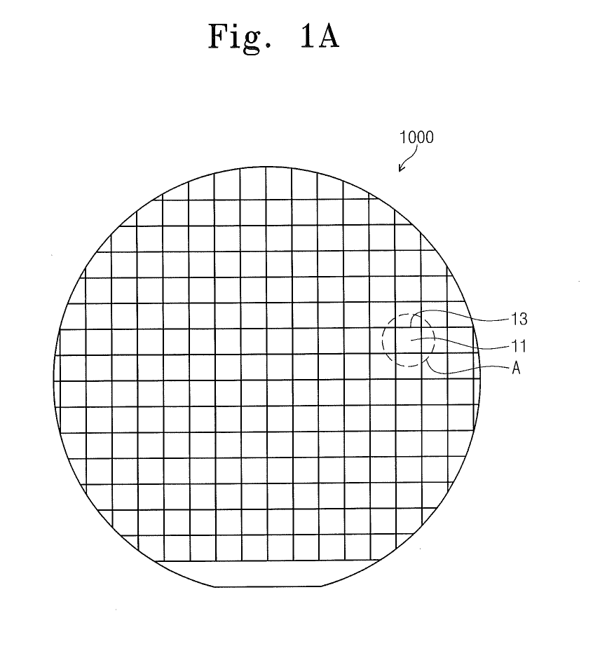

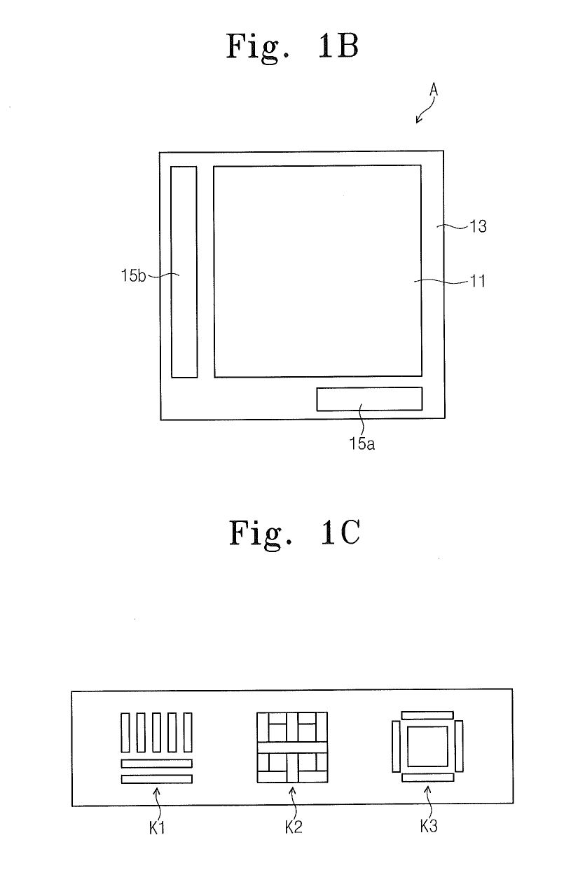

FIG. 1A is a plan view illustrating a wafer for fabricating a semiconductor device. FIG. 1B is an enlarged plan view of a portion “A” of FIG. 1A. FIG. 1C is a plan view illustrating shapes of photo alignment keys.

Referring to FIGS. 1A and 1B, a semiconductor wafer 1000 may include a plurality of semiconductor chips 11 and a scribe lane 13 disposed between the semiconductor chips 11. The semiconductor chips 11 may be arranged along rows and columns on the semiconductor wafer 1000. Each of the semiconductor chips 11 may be an individual semiconductor device including a passive element, an active element, and/or a integrated circuit. After a fabricating method of the semiconductor chips 11 is finished, the semiconductor wafer 1000 may be cut along the scribe lane 13. A test element group (not illustrated), an X-axis photo alignment key 15a and a Y-axis photo alignment key 15b may be formed in the scribe lane 13.

Referring to FIG. 1C, The X-axis and Y-axis photo alignment keys 15a and 15b may be realized as patterns K1, K2, and K3 of various shapes. The X-axis and Y-axis alignment keys 15a and 15b may be realized as local alignment keys, global alignment keys, registration alignment keys, overlay alignment keys, and/or measurement keys according to the purposes of use of the X-axis and Y-axis alignment keys 15a and 15b.

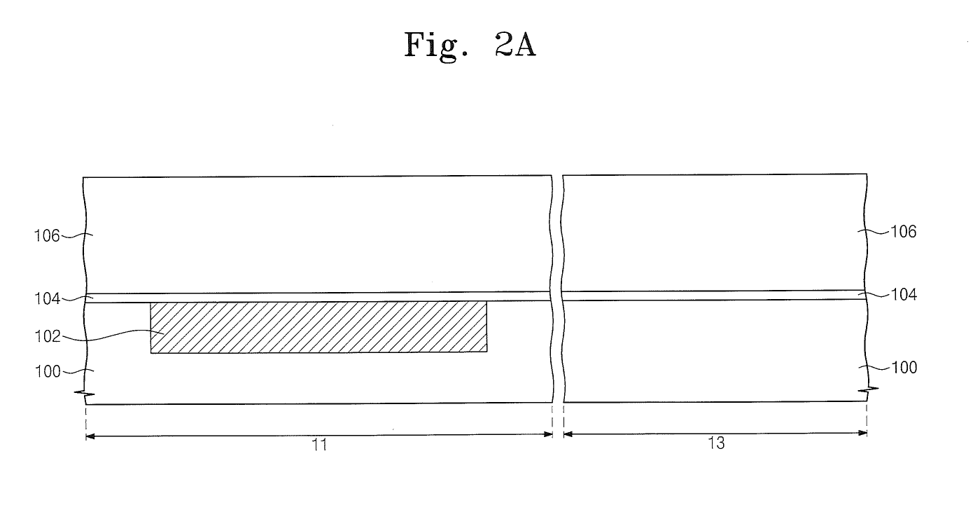

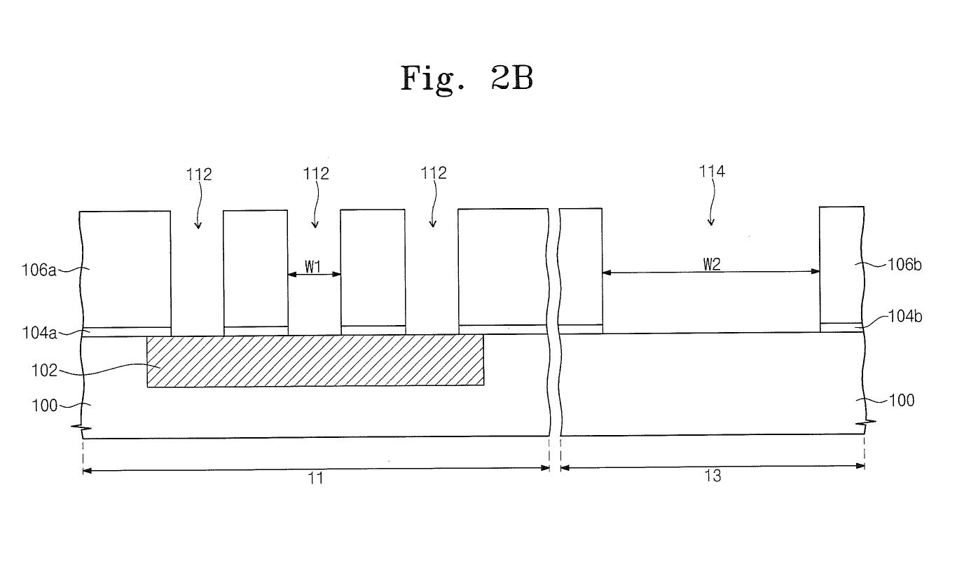

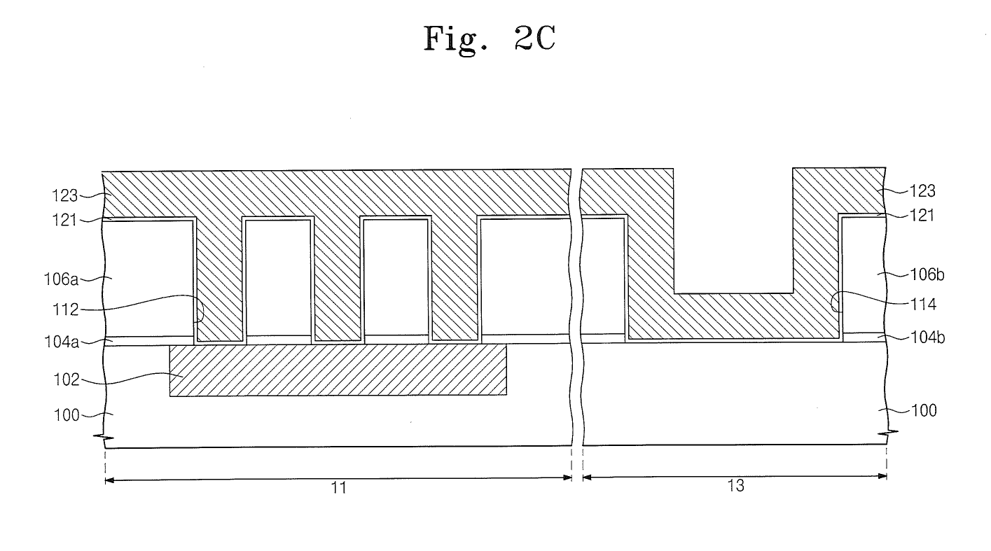

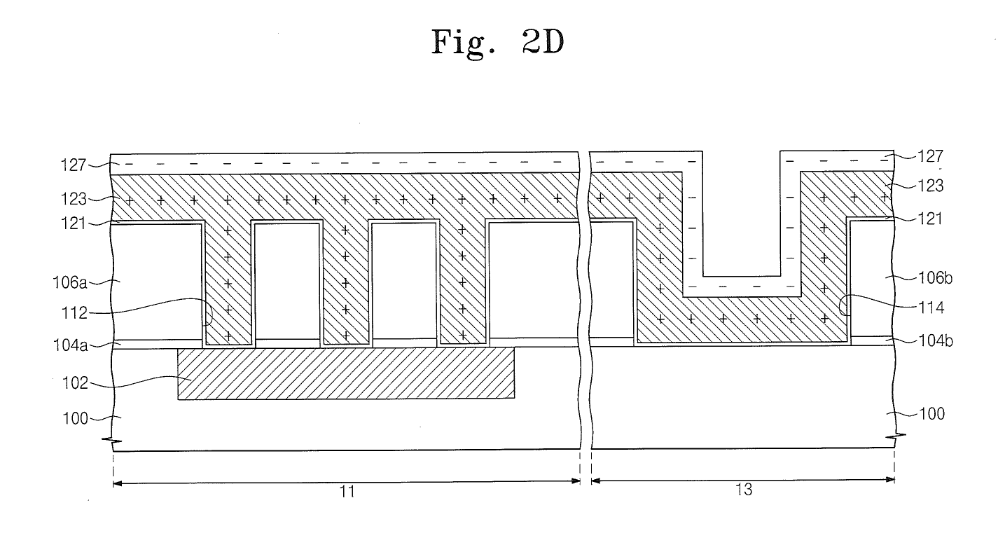

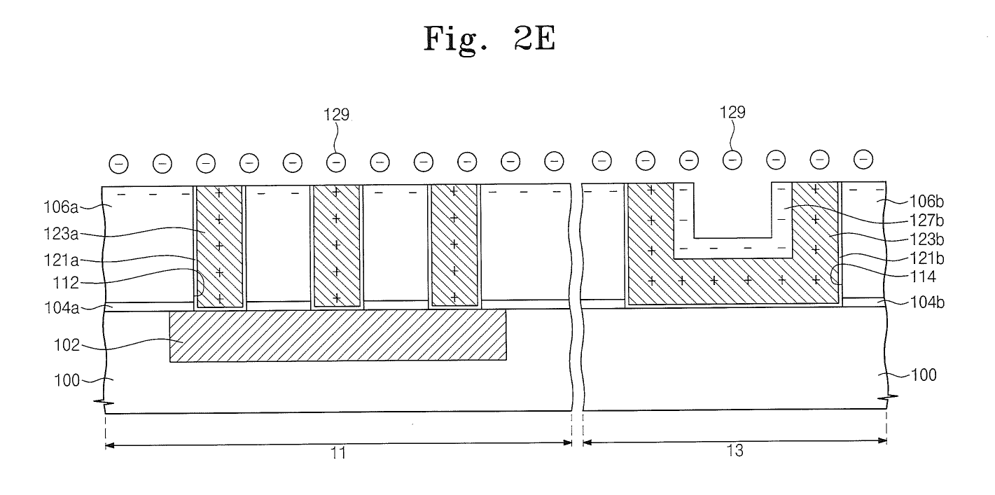

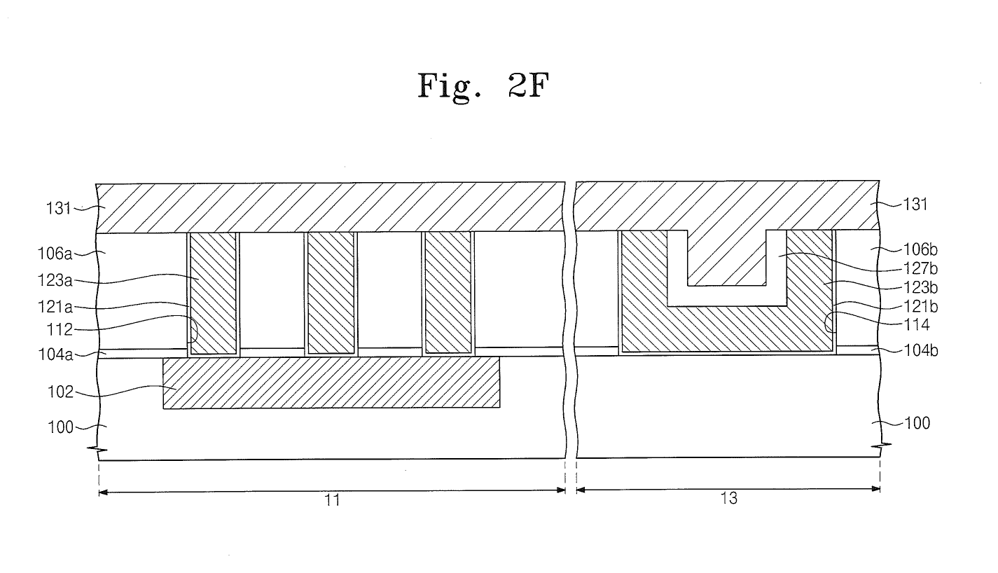

FIG. 2A to 2G are cross-sectional views illustrating a method of fabricating a semiconductor device according to some embodiments of the inventive concept.

Referring to FIG. 2A, a barrier layer 104 and an insulating layer 106 may be sequentially formed on a semiconductor substrate 100.

The semiconductor substrate 100 may include a semiconductor chip region 11 and a scribe region 13. The semiconductor substrate 100 may include silicon (Si), silicon oxide (e.g., SiOH), and/or an insulating layer such as an interlayer dielectric. An individual semiconductor device including a passive element, an active element, and/or an integrated circuit may be formed in the semiconductor chip region 11. Test elements and/or photo alignment keys may be formed in the scribe region 13.

The semiconductor substrate 100 of the semiconductor chip region 11 may include a lower conductive pattern 102. The lower conductive pattern 102 may be a lower interconnection. The lower conductive pattern 102 may be formed of at least one of aluminum (Al), tungsten (W), titanium (Ti), copper (Cu), or any alloy thereof.

The barrier layer 104 formed on the semiconductor substrate 100 may function as an etch stop layer, a chemical mechanical polishing (CMP) stop layer, and/or an impurity blocking layer. When the barrier layer 104 functions as the etch stop layer or the CMP stop layer, the barrier layer 104 may include, for example, a silicon nitride layer and/or a silicon oxynitride layer. When the barrier layer 104 functions as the impurity blocking layer, the barrier layer 104 may include at least one of a silicon nitride (SiN) layer, an aluminum oxide (Al₂O₃) layer, a tantalum (Ta) layer, a tantalum nitride (TaN) layer, a titanium (Ti) layer, a titanium nitride (TiN) layer, a cobalt (Co) layer, a ruthenium (Ru) layer, or a nickel (Ni) layer.

The insulating layer 106 on the barrier layer 104 may be formed of a material having an etch selectivity with respect to the barrier layer 104. For example, if the barrier layer 104 includes a nitride layer, the insulating layer 106 may include an oxide layer. In detail, the insulating layer 106 may include, for example, a silicon oxide layer.

Referring to FIG. 2B, the insulating layer 106 and the barrier layer 104 may be patterned to form contact holes 112 in the semiconductor chip region 11 and to form a photo alignment key trench 114 in the scribe region 13.

In more detail, a photo mask pattern (not illustrated) may be formed on the insulating layer 106, and then the insulating layer 106 exposed by the photo mask pattern and the barrier layer 104 may be successively etched. As a result, a first barrier pattern 104a and a first insulating pattern 106a having the contact holes 112 may be formed in the semiconductor chip region 11, and a second barrier pattern 104b and a second insulating pattern 106b having the photo alignment key trench 114 may be formed in the scribe lane 13.

The contact holes 112 may be formed to expose a top surface of the lower conductive pattern 102. The photo alignment key trench 114 may expose a top surface of the semiconductor substrate 100 in the scribed region 13. The top surface of the semiconductor substrate 100 exposed by the photo alignment key trench 114 may be recessed. A width W2 of the photo alignment key trench 114 may be greater than a width W1 of the contact hole 112. The width W2 of the photo alignment key trench 114 may have a range of several micrometers to several tens micrometers.

Referring to FIG. 2C, a diffusion preventing layer 121 may be formed on the first and second insulating patterns 106a and 106b on the semiconductor substrate 100.

The diffusion preventing layer 121 may be conformally formed to cover inner surfaces of the contact holes 112, an inner surface of the photo alignment key trench 114, and top surfaces of the first and second insulating patterns 106a and 106b. Thus, the diffusion preventing layer 121 may cover the top surface of the lower conductive pattern 102 exposed by the contact holes 112 and the top surface of the semiconductor substrate 100 exposed by the photo alignment key trench 114. The diffusion preventing layer 121 may be formed by a physical vapor deposition (PVD) process, a chemical vapor deposition (CVD) process, or an atomic layer deposition (ALD) process. For example, the diffusion preventing layer 121 may include at least one of a tantalum (Ta) layer, a tantalum nitride (TaN) layer, a titanium (Ti) layer, a titanium nitride (TiN), a cobalt (Co) layer, a ruthenium (Ru) layer, or a nickel (Ni) layer.

A metal plug layer 123 may be formed in the contact holes 112 and the photo alignment key trench 114 having the diffusion preventing layer 121.

The metal plug layer 123 may be formed to completely fill the contact holes 112. Further, the metal plug layer 123 may be conformally formed in the photo alignment key trench 114 having the width W2 greater than the width W1 of the contact hole 112. The metal plug layer 123 may be formed by a PVD process, a CVD process, or an ALD process. For example, the metal plug layer 123 may include at least one of a tungsten (W) layer, an aluminum (Al) layer, a copper (Cu) layer, or any alloy thereof.

Referring to FIG. 2D, a protecting layer 127 may be formed on the metal plug layer 123.

The protecting layer 127 may be formed to completely cover a top surface of the metal plug layer 123. The protecting layer 127 may be conformally formed along a profile of a top surface of the metal plug layer 123 in the scribe region 13. The protecting layer 127 may have a thickness of several angstroms to several tens angstroms. In some embodiments, the protecting layer 127 may have a thickness ranging from about 10 ∪ to 100 ∪. The protecting layer 127 may partially fill the photo alignment key trench 114. In other words, the width W2 of the photo alignment key trench 114 may be greater than a double sum of depositing thicknesses of the diffusion preventing layer 121, the metal plug layer 123, and the protecting layer 127. The protecting layer 127 may be formed of a material having a negative zeta potential value by a pH of a slurry used in a subsequent chemical mechanical polishing (CMP) process. If the protecting layer 127 comes in contact with the slurry having an acidic pH level, the protecting layer 127 may be formed of a material having negative charges. In this case, the pH of the slurry may have a range of about 1 to about 4. More particularly, the pH of the slurry may have a range of about 2 to about 3. In this case, the protecting layer 127 may include, for example, a silicon oxide (SiO₂) layer or a titanium oxide (TiO₂) layer. When the metal plug layer 123 comes in contact with the slurry having the acidic pH level, the metal plug layer 123 may have positive charges.

Referring to FIG. 2E, the CMP process may be performed on the semiconductor substrate 100 having the protecting layer 127.

In detail, the CMP process may be performed on the protecting layer 127 and the metal plug layer 123 until the top surfaces of the first and second insulating patterns 106a and 106b are exposed. Thus, the diffusion preventing layer 121, the metal plug layer 123, and the protecting layer 127 disposed on the top surfaces of the first and second insulating patterns 106a and 106b may be removed in the semiconductor chip region 11 and the scribe region 13. As a result, the protecting layer 127 in the semiconductor chip region 11 may be completely removed, and a first diffusion preventing pattern 121a and a metal plug 123a may be formed in the contact holes 112. The first diffusion preventing pattern 121a may cover the inner surface of the contact hole 112 and the metal plug 123a may be disposed on the first diffusion preventing patterns 121a to fill the contact hole 112. Also, a second diffusion preventing pattern 121b, a metal pattern 123b, and a protecting pattern 127b may be formed to sequentially cover the inner surface of the photo alignment key trench 114 in the scribe region 13.

The CMP process may be a planarizing process which chemically and mechanically polishes a desired material by using the slurry including polishing particles and a chemical material. The slurry for polishing a metal layer (e.g., W, Al, and Cu) may include polishing particles, an oxidizer, and a pH controlling agent. The polishing particles may include silicon particles and/or alumina particles. The oxidizer may oxidize a surface of the metal layer. For example, the oxidizer may include hydrogen peroxide, iron nitrate, or persulfuric acid. The pH controlling agent may control the pH of the slurry for improving polishing characteristics of the metal layer. The pH controlling agent may include an acid solution having a pH of about 1 to about 4. For example, the pH controlling agent may include at least one of sulfuric acid, nitric acid, hydrochloric acid, phosphoric acid, acetic acid, malonic acid, glucosan, or citric acid.

The metal layer may chemically react with the oxidizer to form a metal oxide layer on a surface of the metal layer. The metal oxide layer may be formed at an uppermost portion of the metal layer and then be grinded by the polishing process of the polishing particles so as to be mechanically removed. This mechanism may be repeated to perform the planarizing process of the metal layer.

The polishing particles and the surface of the metal layer may have electrical charges induced by the pH of the slurry. These may be represented as zeta potential values. If the slurry has an acidic pH level (e.g., the pH of about 1 to about 4), the silica particle of the polishing particles may have a negative zeta potential value, and the alumina particle of the polishing particles may have a positive zeta potential value. If the slurry has an acidic pH level (e.g., the pH of about 1 to about 4), the metal layer may have a positive zeta potential value. The semiconductor substrate 100 may have a negative zeta potential value in a pH region of acidity and alkalinity. Thus, if the polishing particles are the silicon particles, an attractive force is applied between the metal layer and the silica particle during the CMP process since the zeta potential value of the silica particle has a polarity opposite to that of the zeta potential value of the metal layer.

Thus, foreign materials such as the silica particles 129 having negative charges and metal oxide particles (not illustrated) may be adhered to a surface of the metal pattern 123b having positive charges in the photo alignment key trench 114 during the CMP process performed on the semiconductor chip region 11 and the scribe region 13. In this case, when photo-alignment process is performed using the photo-alignment key trench 114, a semiconductor substrate may be misaligned, such that a subsequent thin layer pattern may not be formed at a desired position. Additionally, if a chemical wet cleaning process is performed for removing the foreign materials, the first and second insulating patterns 106a and 106b may be etched.

However, according to some embodiments of the inventive concept, the protecting pattern 127b may be formed on the metal pattern 123b in the photo alignment key trench 114. When the CMP process is performed, the protecting pattern 127b may be formed of the material having the charges of the same polarity as the polishing particles to prevent the attractive force from being applied between surface charges of the metal plug layer 123 and the surface charges of the polishing particles. When the protecting pattern 127b comes in contact with the slurry having the acidic pH level, the protecting pattern 127b may have negative charges. Thus, a repulsive force may occur between the protecting pattern 127b in the photo alignment key trench 114 and the silica particles 129 having the negative charges after the CMP process. As a result, the foreign materials such as the silica particles 129 and the metal oxide particles (not illustrated) may not be adsorbed in the photo alignment key trench 114, such that the metal pattern 123b and the protecting pattern 127b may be formed in the photo alignment key trench 114 without an additional chemical wet cleaning process for removing the foreign materials,

In other embodiments, if the width of the photo alignment key trench 114 is less than about 1 pi, even though the protecting pattern 127b has the charges of the same polarity as the charges of the silicon particles 129, the foreign materials such as the silicon particles 129 and the metal oxide particles (not illustrated) may be formed in the photo alignment key trench 114. In this case, after the CMP process, the protecting pattern 127b may be removed to remove the foreign materials in the photo alignment key trench 114. In other words, it is possible to prevent the foreign materials from remaining on the surface of the metal pattern 123b. The protecting pattern 127b may be removed by a chemical wet cleaning process. The protecting pattern 127b may be removed by a process removing a metal oxide layer formed on the metal plug 123a by natural oxidation.

In the semiconductor chip region 11, the top surface of the first insulating pattern 106a and the top surfaces of the metal plugs 123a may be exposed by the CMP process. However, since the top surface of the first insulating pattern 106a may have negative charges, the foreign materials may not be formed on the metal plugs 123a.

Referring to FIG. 2F, an upper conductive layer 131 may be formed on the semiconductor substrate 100 including the metal plugs 123a and the metal pattern 123b.

The upper conductive layer 131 may completely cover the top surfaces of the metal plugs 123a in the semiconductor chip region 11 and may completely fill the photo alignment key trench 114 in the scribe region 13. The upper conductive layer 131 may be formed of at least one of aluminum (Al), tungsten (W), titanium (Ti), copper (Cu), or any alloy thereof.

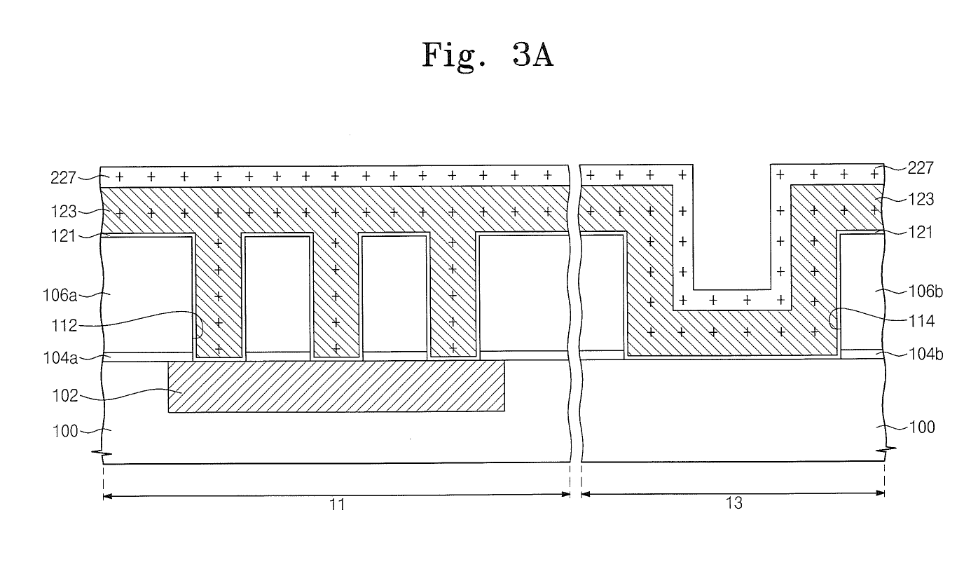

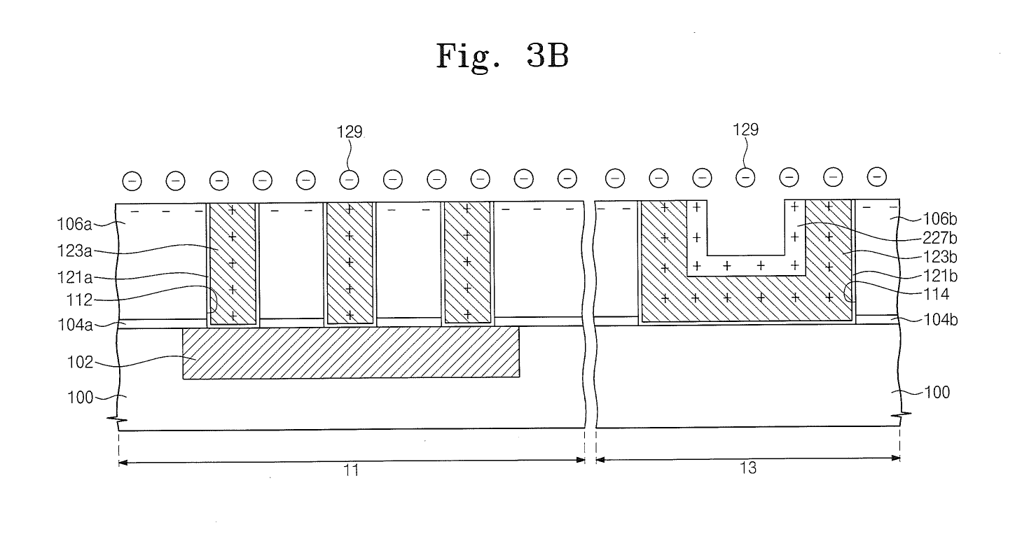

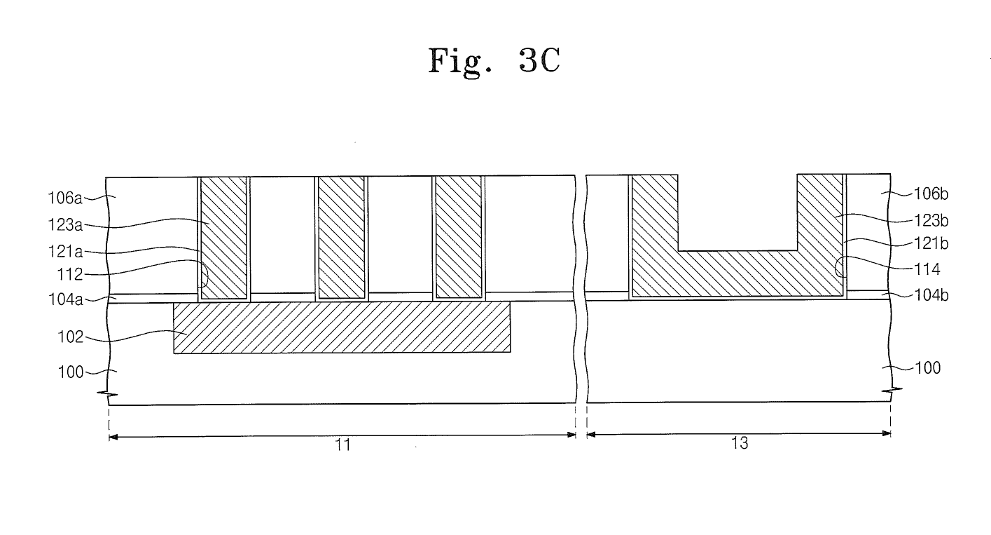

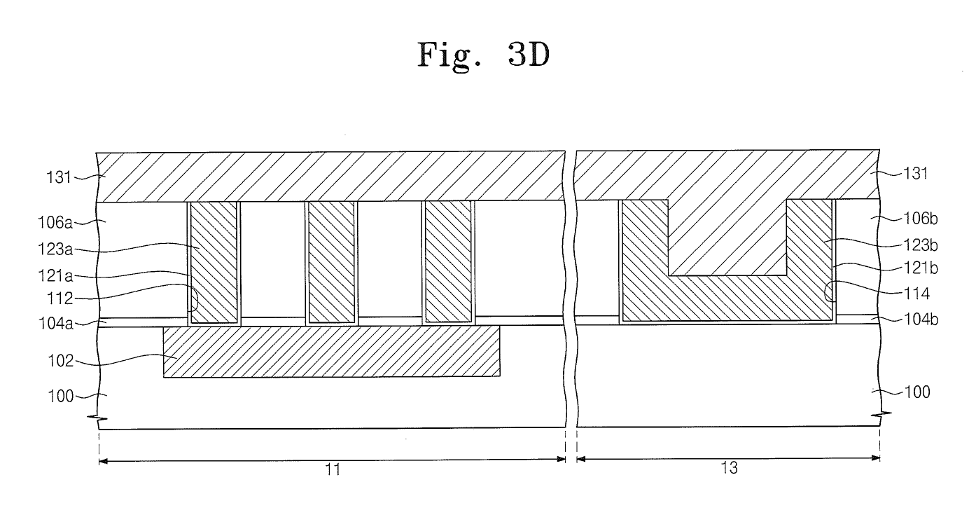

FIG. 3A to 3D are cross-sectional views illustrating a method of fabricating a semiconductor device according to some embodiments of the inventive concept. In the present embodiment, the same elements as described in the embodiment of FIGS. 2A to 2F will be indicated by the same reference numerals or the same reference designators. For the purpose of ease and convenience in explanation, the descriptions to the same elements as in the first embodiment will be omitted or mentioned briefly. The method of fabricating a semiconductor device according to the present embodiment may include the processes described with reference to FIGS. 2A to 2C.

Referring to FIG. 3A, a protecting layer 227 may be formed on the semiconductor substrate 100 including the metal plug layer 123.

The protecting layer 227 may completely cover a top surface of the metal plug layer 123. The protecting layer 227 may conformally cover a profile of the top surface of the metal plug layer 123 in the scribe region 13. The protecting layer 227 may be formed to have a thickness of several Å to several tens Å. The photo alignment key trench 114 may not be filled with the protecting layer 227. Alternatively, the photo alignment key trench 114 may be filled with the protecting layer 227.

The protecting layer 227 may be formed of a material having a zeta potential value of a polarity opposite to that of the zeta potential of the polishing particles included in the slurry used in a subsequent CMP process. In more detail, the protecting layer 227 may be formed of a material having positive charges when it comes in contact with the slurry having the acidic pH level. At this time, the pH of the slurry may have a range of about 1 to about 4. Particularly, the pH of the slurry may have a range of about 2 to about 3. In this case, for example, the protecting layer 227 may include a silicon nitride (Si₃N₄) layer or an aluminum oxide (Al₂O₃) layer. The protecting layer 227 may be formed of a material having an etch selectivity with respect to the metal plug layer 127. This will be described in more detail with reference to FIGS. 3B and 3C.

Referring to FIG. 3B, the CMP process may be performed on the semiconductor substrate 100 having the protecting layer 227.

In more detail, the CMP process may be performed on the protecting layer 227 and the metal plug layer 123 until the top surfaces of the first and second insulating patterns 106a and 106b. Thus, the diffusion preventing layer 121, the metal plug layer 123, and the protecting layer 227 disposed on the top surfaces of the insulating patterns 106a and 106b may be removed in the semiconductor chip region 11 and the scribed region 13. As a result, the protecting layer 227 in the semiconductor chip region 11 may be completely removed, and first diffusion preventing patterns 121a and metal plugs 123a may be formed in the semiconductor chip region 11. The first diffusion preventing patterns 121 a may cover inner surfaces of the contact holes 112, respectively. The metal plugs 123a may fill the contact holes 112, respectively. A second diffusion preventing pattern 121b, a metal pattern 123b, and a protecting pattern 227b may be formed to sequentially cover the inner surface of the photo alignment key trench 114 in the scribe region 13.

If the pH of the slurry is the acidic level (e.g., within a range of about 1 to about 4), silica particles 129 included in the slurry may have negative charges. Thus, the silica particles 129 may be adsorbed on a surface of the protecting pattern 227b having the positive charges during the CMP process. As a result, the silica particles 129 and the metal oxide particles (not illustrated) may be adsorbed in the photo alignment key trench 114 in the scribe region 13.

Referring to FIG. 3C, the protecting pattern 227b on which the silicon particles 129 and the metal oxide particles are adsorbed may be removed.

The protecting pattern 227b may be removed by a chemical wetting cleaning process. When the chemical wetting cleaning process is performed, the metal pattern 123b is not removed since the metal pattern 123b has an etch selectivity with respect to the protecting pattern 227b. As a result, it is possible to remove the foreign materials such as the silica particles 129 and the metal oxide particles formed in the photo alignment key trench 114.

Referring to FIG. 3D, an upper conductive layer 131 may be formed on the semiconductor substrate 100 having the metal plugs 123a and the metal pattern 123b.

The upper conductive layer 131 may completely cover the top surfaces of the metal plugs 123a in the semiconductor chip region 11 and may completely fill the photo alignment key trench 114 in the scribe region 13.

According to some embodiments of the inventive concept, the protecting layer may be conformally formed in the photo alignment key trench having the metal plug layer. When the CMP process is performed on the protecting layer and metal plug layer, the protecting layer has negative charges. Thus, the repulsive force may be generated between the protecting layer and the slurry including the polishing particles having negative charges. As a result, it is possible to prevent the foreign materials such as the polishing particles from being adsorbed in the photo alignment key trench.

According to other embodiments of the inventive concept, the protecting layer may have positive charges and the etch selectivity with respect to the metal plug layer, Thus, when the CMP process is performed on the protecting layer and metal plug layer, the polishing particles in the slurry may be adsorbed in the photo alignment key trench. In this case, the protecting pattern may be removed from the photo alignment key trench, such that the foreign materials may be removed from the photo alignment key trench without damage of the metal pattern formed in the photo alignment key trench.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A method of fabricating a semiconductor device comprising:
forming an insulating pattern including a trench on a semiconductor substrate;
conformally forming a metal layer covering an inner surface of the trench on the insulating patterns;
conformally forming a protecting layer on the metal layer; and
performing a chemical mechanical polishing (CMP) process on the protecting layer and the metal layer to expose a top surface of the insulating pattern, thereby forming a metal pattern and a protecting pattern in the trench,
wherein the CMP process uses a slurry including polishing particles having negative charges.

2. The method of claim 1, wherein the slurry has a pH of about 1 to about 4; and wherein the protecting layer has negative charges at least due to the slurry.

3. The method of claim 2, wherein the protecting layer includes a silicon oxide layer and/or a titanium oxide layer.

4. The method of claim 1, wherein the slurry has a pH of about 1 to about 4; and
wherein the protecting layer has positive charges at least due to the slurry.

5. The method of claim 4, wherein the protecting layer includes a silicon nitride layer and/or an aluminum oxide layer.

6. The method of claim 4, further comprising
removing the protecting pattern after performing the CMP process.

7. The method of claim 1, wherein the polishing particles are silica particles.

8. The method of claim 1, wherein the metal layer includes at least one of tungsten, aluminum, copper, or any alloy thereof.

9. The method of claim 1, wherein a thickness of the metal layer is less than a half of a width of the trench.

10. A method of fabricating a semiconductor device comprising:
forming an insulating pattern having a contact hole and a photo alignment key trench on a semiconductor substrate, the photo alignment key trench having a width greater than a width of the contact hole;
forming a metal plug layer on the insulating pattern, the metal plug layer filling the contact hole and covering an inner surface of the photo alignment key trench;
conformally forming a protecting layer on the metal plug layer; and
performing a chemical mechanical polishing (CMP) process on the protecting layer and the metal plug layer by employing a slurry including polishing particles having charges,
wherein the protecting layer includes a material having charges of the same polarity as the polishing particles in the slurry.

11. The method of claim 10, wherein the slurry has a pH of about 1 to about 4; and wherein the protecting layer has negative charges at least due to the slurry.

12. The method of claim 10, wherein the protecting layer includes a silicon oxide layer and/or a titanium oxide layer.

13. The method of claim 10, wherein the polishing particles are silica particles.

14. The method of claim 10, wherein performing the CMP process comprises forming a metal pattern and a protecting pattern covering a surface of the metal pattern in the photo alignment key trench and a metal plug in the contact hole.

15. The method of claim 14, further comprising removing the protecting pattern after performing the CMP process.

16. The method of claim 1, wherein the method comprises forming at least two insulating patterns on the semiconductor substrate.

17. The method of claim 1, wherein the metal layer has a positive zeta potential value.

18. The method of claim 7, wherein the silica particles are adsorbed on a surface of the protecting pattern.
